(19) United States
(12) Patent Application Publication
(10) Pub. No.: US 2019/0208627 A1
(43) Pub. Date: Jul. 4, 2019

(54) FLEXIBLE PRINTED CIRCUIT APPLIED TO DISPLAY PANEL AND DISPLAY DEVICE

(71) Applicants: HKC Corporation Limited, SHENZHEN (CN); CHONGQING HKC OPTOELECTRONICS TECHNOLOGY CO., LTD., CHONGQING (CN)

(72) Inventor: SHUOZHEN LIANG, CHONGQING (CN)

(21) Appl. No.: 16/311,667

(22) PCT Filed: Aug. 10, 2017
(86) PCT No.: PCT/CN2017/096713

§ 371 Date: Dec. 19, 2018

(30) Foreign Application Priority Data
Jun. 6, 2017 (CN) 201720654660.0

(51) Int. Cl. H05K 1/02; H05K 1/18

(52) U.S. Cl. CPC H05K 1/0281; H05K 2201/2009; H05K 2201/10128; H05K 1/189

(57) ABSTRACT

The present application discloses a Flexible Printed Circuit (FPC) applied to a display panel, including: a first connecting edge connected to the display panel; and a second connecting edge connected to a control circuit board; both ends of the first connecting edge and the second connecting edge are connected and provided with a side edge on which a stress dispersion part is provided; the stress dispersion part includes a recess provided on the side edge, and the profile of the recess is an are segment; the recess is provided on the side edge; and one end of the recess is connected to an endpoint of the first connecting edge, and the other end of the recess is connected to an endpoint of the second connecting edge.

### TECHNICAL FIELD

The present application relates to the technical field of display, and in particular, to a Flexible Printed Circuit (FPC) applied to a display panel and a display device.

### BACKGROUND

A display has many advantages such as thin body, power-saving, and no radiation, and thus has been widely used. Most displays currently available on the market are backlight displays, which include a display panel and a backlight module. The working principle of the display panel is to place liquid crystal molecules in two parallel substrates, and apply driving voltages on the two substrates to control the rotation direction of the liquid crystal molecules to refract the light of the backlight module to generate a picture.

Thin Film Transistor-Liquid Crystal Display (TFT-LCD) has gradually become a leading role in the display field due to its low power consumption, excellent picture quality, and higher production yield. Similarly, the TFT-LCD includes a display panel and a backlight module. The display panel includes a Color Film Substrate (CF Substrate) (also called a color filter substrate) and a Thin Film Transistor Substrate (TFT Substrate), and transparent electrodes are disposed on opposite sides of the substrates. A Liquid Crystal (LC) molecule layer is sandwiched between the two substrates. The display panel changes the polarization state of the light by means of the control of the liquid crystal molecule orientation by the electric field, and achieves penetration and blocking of a light path by means of a polarizing plate, thereby achieving the objective of display.

COF (Chip On Flex or Chip On Film), i.e., a grain flexible-film packaging technology for fixing a driver IC on an FPC, is a technology that uses a flexible additional control circuit board as a package chip carrier to bond the chip to the flexible substrate circuit.

For the current curved-surface design application, because the display panel is to be bent, the FPC would be easily strained, resulting in an abnormality in display.

### SUMMARY

The technical problem to be solved by the present application is to provide an FPC applied to a display panel capable of effectively avoiding strain caused by bending.

In addition, the present application also provides a display device.

The objective of the present application is implemented by means of the following technical solution:

an FPC applied to a display panel, including:

a first connecting edge connected to the display panel; and

a second connecting edge connected to a control circuit board;

both ends of the first connecting edge and the second connecting edge are connected and provided with a side edge on which a stress dispersion part is provided.

The side edge includes a first side edge and a second side edge, and the stress dispersion part is provided on the first side edge or the second side edge. In this way, the stress dispersion part is provided on the first side edge or the second side edge. Such setting is suitable for a side edge where no stress dispersion part is provided being fixed and not bent, and a side edge to be bent can disperse the torque generated by bending the display panel, so that the stressed points on the FPC are dispersed to effectively avoid the tearing of the FPC, and the wiring strain caused by the bending of the FPC can be reduced, thereby ensuring a better display effect of the display panel, effectively avoiding the position where the FPC is connected to the display panel from being strained, further enabling normal display of the display panel, and ensuring the yield for manufacturing the display panel with a curved surface.

The side edge includes a first side edge and a second side edge, and the stress dispersion parts are symmetrically provided on the first side edge and the second side edge. In this way, the stress dispersion parts are symmetrically provided on the first side edge and the second side edge, facilitating production and manufacture of the FPC. Moreover, the bending curvatures of the first side edge and the second side edge can be effectively the same or similar, and the torque generated by bending the display panel can be dispersed, so that the stressed points on the FPC are dispersed, thereby effectively avoiding the tearing of the FPC, effectively preventing the position where the FPC is connected to the display panel from being strained, and further avoiding the abnormal display caused by the strain of the display panel, thereby ensuring the yield for manufacturing the display panel with a curved surface, and effectively reducing the scrap cost of the display panel.

The stress dispersion part includes an arched part provided on the side edge.

The stress dispersion part includes a recess provided on the side edge, and the profile of the recess is an arc segment. In this way, setting the profile of the recess as an arc segment can disperse the stressed points on the FPC better. As the curvature of the FPC when bending changes, the arc segment can dynamically disperse the stressed points on the FPC, so that the stressed points on the FPC are dispersed, and the stress on the stressed points is much less than the stress limit of the FPC, thereby effectively avoiding the tearing of the FPC, and effectively avoiding the position where the FPC is connected to the display panel from being strained.

The recess is provided on the side edge, one end of the recess is connected to an endpoint of the first connecting edge, and the other end of the recess is connected to an endpoint of the second connecting edge. In this way, setting the entire first side edge or/and second side edge as an arc segment is suitable for a side edge where no recess is provided being fixed and not bent, and a side edge to be bent can disperse the torque generated by bending the display panel. As the curvature of the FPC when bending changes, the arc segment can dynamically disperse the stressed points on the FPC, so that the stressed points on the FPC are dispersed, thereby effectively avoiding the tearing of the FPC, effectively avoiding the position where the FPC is connected to the display panel from being strained, and further avoiding the abnormal display caused by the strain of the display panel.

Both ends of the recess are intersected with the side edge. In this way, the torque generated by bending the display panel can be dispersed, so that the stressed points of the FPC are dispersed, thereby effectively avoiding the tearing of the FPC, effectively avoiding the position where the FPC is connected to the display panel from being strained, and greatly reducing the reject ratio of the display panel with a curved surface, without increasing any cost.

The profile of the recess includes a first linear segment and a second linear segment; and a first end of the first linear segment is intersected with a first end of the second linear segment at a central position of the side edge. In this way, the stressed points on the FPC can be dispersed better. As the curvature of the FPC when bending changes, the recess can dynamically disperse the stressed points on the FPC, so that the stressed points on the FPC are dispersed, and the stress on the stressed points is much less than the stress limit of the FPC, thereby effectively avoiding the tearing of the FPC and effectively avoiding the position where the FPC is connected to the display panel from being strained.

A second end of the first linear segment and a second end of the second linear segment are intersected with the first connecting edge and the second connecting edge, respectively. In this way, the entire first side edge or/and the second side edge are set as recesses, so that the torque generated by bending the display panel can be dispersed. As the curvature of the FPC when bending changes, the recess can dynamically disperse the stressed points on the FPC, so that the stressed points on the FPC are dispersed, thereby effectively avoiding the tearing of the FPC, effectively avoiding the position where the FPC is connected to the display panel from being strained, and further avoiding the abnormal display caused by the strain of the display panel, and greatly reducing the reject ratio of the display panel with a curved surface, without increasing any cost.

The second end of the first linear segment and the second end of the second linear segment are intersected with the side edge, separately. In this way, the torque generated by bending the display panel can be dispersed, so that the stressed points on the FPC are dispersed, thereby effectively avoiding the tearing of the FPC, effectively avoiding the position where the FPC is connected to the display panel from being strained, and greatly reducing the reject ratio of the display panel with a curved surface, is made without increasing any cost.

According to another aspect of the present application, the present application also discloses a display device, which includes a display panel, a control circuit board, and the FPC according to any one of the foregoing embodiments.

According to the present application, since a stress dispersion part is provided on a side edge, the torque generated by bending the display panel can be effectively dispersed, so that the stressed points on the FPC are dispersed, thereby effectively avoiding the tearing of the FPC, effectively avoiding the position where the FPC is connected to the display panel from being strained, further enabling normal display of the display panel, ensuring the yield for manufacturing the display panel with a curved surface, and effectively reducing the scrap cost of the display panel. Moreover, the wiring strain caused by pulling the bent FPC can be reduced, thereby ensuring a better display effect of the display panel, so as to improve the market competitiveness of the display panel. The FPC can be made only by providing a stress dispersion part on a side edge of a chip on panel, so that the reject ratio of the display panel with a curved surface can be greatly reduced without increasing any cost. Such setting can produce a better FPC with the side edge being provided with a stress dispersion part only by simply modifying the existing production line, rather than replacing the entire production line; the modification cost is low, and therefore, the production cost is saved. Moreover, the FPC on the prepared display panel with a curved surface can also be simply modified, and therefore, the display effect of the display panel can be greatly improved in low modification cost.

### BRIEF DESCRIPTION OF DRAWINGS

FIG. 1 is a section view of a connection mode of an FPC according to an embodiment of the present application;

FIG. 2 is a top view of a connection mode of an FPC according to an embodiment of the present application;

FIG. 3 is a plan view of an exemplary FPC according to an embodiment of the present application;

FIG. 4 is a plan view of an FPC according to another embodiment of the present application;

FIG. 5 is a plan view of an FPC according to another embodiment of the present application;

FIG. 6 is a plan view of an FPC according to another embodiment of the present application;

FIG. 7 is a plan view of an FPC according to another embodiment of the present application;

FIG. 8 is a plan view of an FPC according to another embodiment of the present application;

FIG. 9 is a plan view of an FPC according to another embodiment of the present application;

FIG. 10 is a plan view of an FPC according to another embodiment of the present application;

FIG. 11 is a plan view of an FPC according to another embodiment of the present application;

FIG. 12 is a plan view of an FPC according to another embodiment of the present application;

FIG. 13 is a structural schematic diagram of a display device according to an embodiment of the present application.

### DETAILED DESCRIPTION

The specific structure and function details disclosed herein are merely representative, and are intended to describe exemplary embodiments of the present application. However, the present application can be specifically embodied in many alternative forms, and should not be interpreted be to limited to the embodiments described here.

In the description of the present application, it should be understood that, orientation or position relationships indicated by the terms “center”, “transversal”, “upper”, “lower”, “left”, “right”, “vertical”, “horizontal”, “top”, “bottom”, “inner”, “outer”, etc. are based on the orientation or position relationships as shown in the drawings, merely for ease of the description of the present application and simplifying the description only, rather than indicating or implying that the indicated device or element must have a particular orientation or be constructed and operated in a particular orientation. Therefore, these terms should not to be understood as a limitation to the present application. In addition, the terms “first”, “second” are merely for a descriptive purpose, and cannot to be understood to indicate or imply a relative importance, or implicitly indicate the number of the indicated technical features. Hence, the features defined by “first”, “second” can explicitly or implicitly include one or more of the features. In the description of the present application, “a plurality of” means two or more, unless otherwise stated. In addition, the term “comprise” and any variations thereof is intended to cover a non-exclusive inclusion.

In the description of the present application, it should be understood that, unless otherwise specified and defined, the terms “install”, “connected with”, “connected to” should be comprehended in a broad sense. For example, these terms may be comprehended as being fixedly connected, detachably connected or integrally connected; mechanically connected or electrically connected; or directly connected or indirectly connected through an intermediate medium, or in an internal communication between two elements. The specific meanings about the foregoing terms in the present application may be understood for those skilled in the art according to specific circumstances.

The terms used herein are merely for the purpose of describing the particular embodiments, and are not intended to limit the exemplary embodiments. As used herein, the singular forms “a”, “an” are intended to include the plural forms as well, unless otherwise indicated in the context dearly. It will be further understood that the terms “comprise” and/or “include” used herein, specifies the presence of stated features, integers, steps, operations, elements and/or components, but do not preclude the presence or addition of one or more other features, integers, steps, operations, elements, components and/or combinations thereof.

The present application is further described below with reference to the accompanying drawings and preferred embodiments.

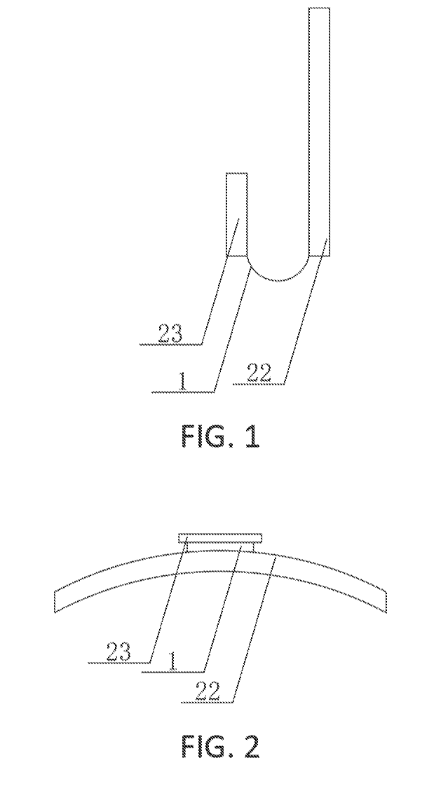

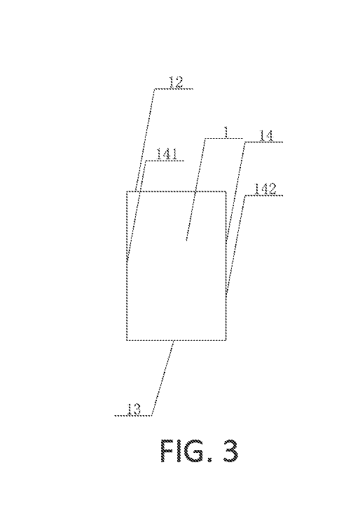

As shown in FIGS. 1-3, an exemplary FPC 1 applied to a display panel is illustrated. The FPC 1 includes a first connecting edge 12 connected to a display panel 22, and a second connecting edge 13 connected to a control circuit board 23; both ends of the first connecting edge 12 and the second connecting edge 13 are connected and provided with two linear edges; and the first connecting edge 12, the second connecting edge 13, and the two linear edges form a rectangular structure.

For the current curved-surface design application of the panel, because the display panel 22 is to be bent, the FPC 1 of the rectangular structure connected to the display panel 22 makes the control circuit board 23 adopt a segmented design, so that the first connecting edge 12 and the second connecting edge 13 are made narrower, and thus, the problem of straining the FPC 1 caused by the excessive bending of the control circuit board 23 can be effectively avoided.

Further research shows that due to the limitations of the thickness and size of the display panel 22, when the FPC 1 connects the display panel 22 and the control circuit board 23, the FPC 1 needs to be bent to effectively perform connection; however, although the control circuit board 23 adopts a segmented design, the problem of straining the FPC 1 during bending cannot be solved, resulting in an abnormality in display of the display panel 22 with a curved surface.

The present application is further described below with reference to FIGS. 1, 2, and 4-12 and preferred embodiments.

The present application discloses an FPC 1 applied to a display panel. The FPC 1 includes a first connecting edge 12 connected to the display panel 22, and a second connecting edge 13 connected to a control circuit board 23; both ends of the first connecting edge 12 and the second connecting edge 13 are connected and provided with a side edge 14 on which a stress dispersion part 16 is provided.

By providing the stress dispersion part 16 on the side edge 14, the torque generated by bending the display panel 22 can be effectively dispersed, so that the stressed points on the FPC 1 are dispersed, thereby effectively avoiding the tearing of the FPC 1, effectively avoiding the position where the FPC 1 is connected to the display panel 22 from being strained, further enabling normal display of the display panel 22, ensuring the yield for manufacturing the display panel 22 with a curved surface, and effectively reducing the scrap cost of the display panel 22. Moreover, the wiring strain caused by pulling the bent FPC 1 can be reduced, thereby ensuring a better display effect of the display panel 22. Moreover, the FPC 1 can be made only by providing a stress dispersion part 16 on a side edge 14 of a chip on panel, so that the reject ratio of the display panel 22 with a curved surface can be greatly reduced without increasing any cost. Such setting can produce a better FPC 1 with the side edge 14 being provided with a stress dispersion part 16 only by simply modifying the existing production line, rather than replacing the entire production line; the modification cost is low, and therefore, the production cost is saved. Moreover, the FPC 1 on the prepared display panel 22 with a curved surface can also be simply modified, and therefore, the display effect of the display panel 22 can be greatly improved in low modification cost.

The side edge 14 includes a first side edge 141 and a second side edge 142, and the stress dispersion part 16 is provided on the first side edge 141 or the second side edge 142. The stress dispersion part 16 is provided on the first side edge 141 or the second side edge 142, such setting is suitable for a side edge where no stress dispersion part 16 is provided being fixed and not bent, and a side edge to be bent can disperse the torque generated by bending the display panel 22, so that the stressed points on the FPC 1 are dispersed to effectively avoid the tearing of the FPC 1, and the wiring strain caused by pulling the bent FPC 1 can be reduced, thereby ensuring a better display effect of the display panel 22, effectively avoiding the position where the FPC 1 is connected to the display panel 22 from being strained, further enabling normal display of the display panel 22, ensuring the yield for manufacturing the display panel 22 with a curved surface, and effectively reducing the scrap cost of the display panel 22. Moreover, the setting of the stress dispersion part 16 can effectively save production consumables of the FPC 1, is more environment-friendly, can further save the production cost of the display panel 22, and is beneficial to improve the market competitiveness of the display panel 22.

The side edge 14 includes a first side edge 141 and a second side edge 142, and the stress dispersion parts 16 are symmetrically provided on the first side edge 141 and the second side edge 142. The stress dispersion parts 16 are symmetrically provided on the first side edge 141 and the second side edge 142, facilitating production and manufacture of the FPC 1. Moreover, the bending curvatures of the first side edge 141 and the second side edge 142 can be effectively the same or similar, and the torque generated by bending the display panel 22 can be dispersed, so that the stressed points on the FPC 1 are dispersed, thereby effectively avoiding the tearing of the FPC 1, effectively preventing the position where the FPC 1 is connected to the display panel 22 from being strained, and further avoiding the abnormal display caused by the strain of the display panel 22, thereby ensuring the yield for manufacturing the display panel 22 with a curved surface, and effectively reducing the scrap cost of the display panel 22. Moreover, the wiring strain caused by pulling the bent FPC 1 can be reduced, thereby ensuring a better display effect of the display panel 22. Moreover, the setting of the stress dispersion part 16 can effectively save production consumables of the FPC 1, can further save the production cost of the display panel 22, and is more environment-friendly.

The stress dispersion part 16 includes a recess 11 provided on the side edge, and the profile of the recess 11 is an arc segment 111. The setting of the arc segment 111 can disperse the stressed points on the FPC 1 better. As the curvature of the FPC 1 when bending changes, the arc segment 111 can dynamically disperse the stressed points on the FPC 1, so that the stressed points on the FPC 1 are dispersed, and the stress on the stressed points is much less than the stress limit of the FPC 1, thereby effectively avoiding the tearing of the FPC 1, effectively avoiding the position where the FPC 1 is connected to the display panel 22 from being strained, and further avoiding the abnormal display caused by the strain of the display panel 22, thereby ensuring the yield for manufacturing the display panel 22 with a curved surface, and effectively reducing the scrap cost of the display panel 22. Moreover, the wiring strain caused by pulling the bent FPC 1 can be reduced, thereby ensuring a better display effect of the display panel 22. Moreover, the setting of the recess can effectively save production consumables of the FPC 1, is more environment-friendly, and can further save the production cost of the display panel 22.

In some embodiments, the FPC may be a COF.

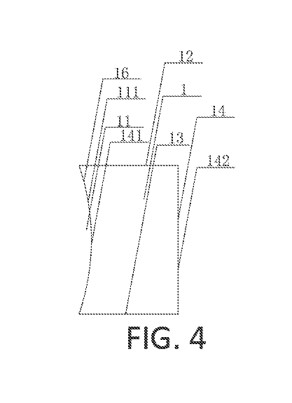

As still another embodiment of the present application, as shown in FIG. 4, the recess 11, the profile of which is an arc segment 111, is provided on the first side edge 141 or the second side edge 142; and one end of the arc segment 111 is connected to an endpoint of the first connecting edge 12, and the other end of the arc segment 111 is connected to an endpoint of the second connecting edge 13. Setting the entire first side edge 141 or second side edge 142 as a recess 11 is suitable for a side edge where no recess 11 is provided being fixed and not bent, and a side edge to be bent can disperse the torque generated by bending the display panel 22. As the curvature of the FPC 1 when bending changes, the recess 11 can dynamically disperse the stressed points on the FPC 1, so that the stressed points on the FPC 1 are dispersed, thereby effectively avoiding the tearing of the FPC 1, effectively avoiding the position where the FPC 1 is connected to the display panel 22 from being strained, and further avoiding the abnormal display caused by the strain of the display panel 22. Moreover, the reject ratio of the display panel 22 with a curved surface can be greatly reduced without increasing any cost, thereby ensuring the yield for manufacturing the display panel 22 with a curved surface, and effectively reducing the scrap cost of the display panel 22.

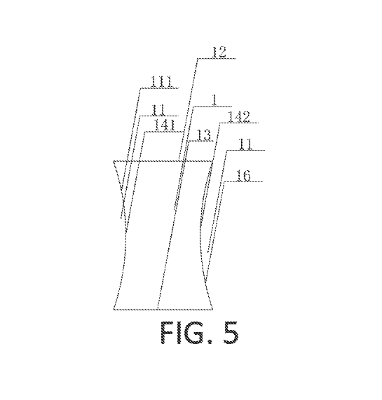

As still another embodiment of the present application, as shown in FIG. 5, the recess 11, the profile of which is an arc segment 111, is provided on the first side edge 141 and the second side edge 142; and one end of the arc segment 111 is connected to an endpoint of the first connecting edge 12, and the other end of the arc segment 111 is connected to an endpoint of the second connecting edge 13. Setting the entire first side edge 141 and second side edge 142 as a recess 11 facilitates production and manufacture of the FPC 1. Moreover, the bending curvatures of the first side edge 141 and the second side edge 142 can be effectively the same or similar, and the torque generated by bending the display panel 22 can be dispersed. As the curvature of the FPC 1 when bending changes, the recess 11 can dynamically disperse the stressed points on the FPC 1, so that the stressed points on the FPC 1 are dispersed, thereby effectively avoiding the tearing of the FPC 1, effectively avoiding the position where the FPC 1 is connected to the display panel 22 from being strained, and further avoiding the abnormal display caused by the strain of the display panel 22. Moreover, the reject ratio of the display panel 22 with a curved surface can be greatly reduced without increasing any cost. Moreover, the setting of the recess 11 can effectively save production consumables of the FPC 1, is more environment-friendly, and can further save the production cost of the display panel 22.

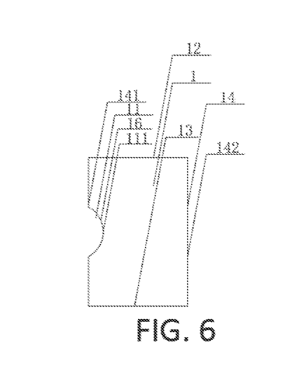

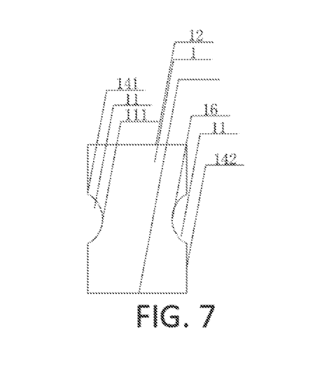

As still another embodiment of the present application, as shown in FIGS. 6 and 7, both ends of the recess 11, the profile of which is an arc segment 111, are intersected with the side edge. Since the bending setting of the FPC 1 is generally performed on the central points of the first side edge 141 and the second side edge 142, the arc segment 111 is provided at the central point of the side edge, and the side edge to be bent can disperse the torque generated by bending the display panel 22, so that the stressed points on the FPC 1 are dispersed, thereby effectively avoiding the tearing of the FPC 1, effectively preventing the position where the FPC 1 is connected to the display panel 22 from being strained, and greatly reducing the reject ratio of the display panel 22 with a curved surface, without increasing any cost. Moreover, the recess 11 is only provided at the central point, and thus the area of the FPC 1 can be effectively enlarged, so that more package chips can be provided on the FPC 1, thereby ensuring the high utilization rate of the FPC 1.

The profile of the recess includes a first linear segment 112 and a second linear segment 113; and a first end of the first linear segment 112 is intersected with a first end of the second linear segment 113 at a central position of the side edge 14. Since the bending setting of the FPC 1 is performed on the central points of the first side edge 141 and the second side edge 142, the arc segment 111 is provided at the central point of the side edge. Such setting of the recess 11 can disperse the stressed points on the FPC 1 better. As the curvature of the FPC 1 when bending changes, the recess 11 can dynamically disperse the stressed points on the FPC 1, so that the stressed points on the FPC 1 are dispersed, and the stress on the stressed points is much less than the stress limit of the FPC 1, thereby effectively avoiding the tearing of the FPC 1, effectively avoiding the position where the FPC 1 is connected to the display panel 22 from being strained, and further avoiding the abnormal display caused by the strain of the display panel 22, thereby ensuring the yield for manufacturing the display panel 22 with a curved surface, and effectively reducing the scrap cost of the display panel 22. Moreover, the wiring strain caused by pulling the bent FPC 1 can be reduced, thereby ensuring a better display effect of the display panel 22. Moreover, the setting of the recess 11 can effectively save production consumables of the FPC 1, is more environment-friendly, and can further save the production cost of the display panel 22.

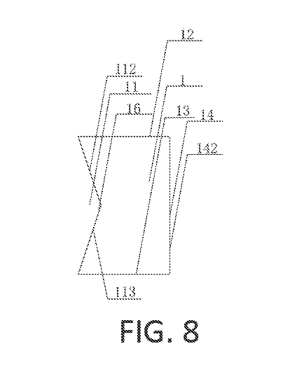

As still another embodiment of the present application, as shown in FIG. 8, a second end of the first linear segment 112 and a second end of the second linear segment 113 are intersected with the first connecting edge 12 and the second connecting edge 13, respectively. Setting the entire first side edge 141 or/and the second side edge 142 as a recess 11 can disperse the torque generated by bending the display panel 22. As the curvature of the FPC 1 when bending changes, the recess 11 can dynamically disperse the stressed points on the FPC 1, so that the stressed points on the FPC 1 are dispersed, thereby effectively avoiding the tearing of the FPC 1, effectively avoiding the position where the FPC 1 is connected to the display panel 22 from being strained, and further avoiding the abnormal display caused by the strain of the display panel 22. Moreover, the reject ratio of the display panel 22 with a curved surface can be greatly reduced without increasing any cost, thereby ensuring the yield for manufacturing the display panel 22 with a curved surface, and effectively reducing the scrap cost of the display panel 22.

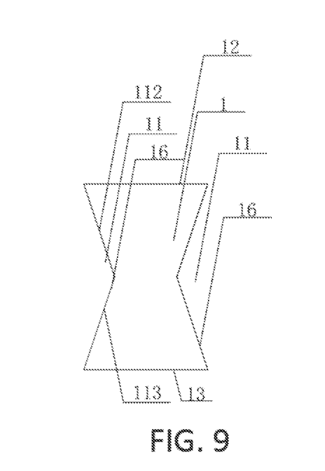

As still another embodiment of the present application, as shown in FIG. 9, the second end of the first linear segment 112 and the second end of the second linear segment 113 are intersected with the first connecting edge 12 and the second connecting edge 13, respectively. Setting the entire first side edge 141 and the second side edge 142 as a recess 111 facilitates production and manufacture of the FPC 1. Moreover, the bending curvatures of the first side edge 141 and the second side edge 142 can be effectively the same or similar, and the torque generated by bending the display panel 22 can be dispersed. As the curvature of the FPC 1 when bending changes, the recess 111 can dynamically disperse the stressed points on the FPC 1, so that the stressed points on the FPC 1 are dispersed, thereby effectively avoiding the tearing of the FPC 1, effectively avoiding the position where the FPC 1 is connected to the display panel 22 from being strained, and further avoiding the abnormal display caused by the strain of the display panel 22. Moreover, the reject ratio of the display panel 22 with a curved surface can be greatly reduced without increasing any cost. Moreover, the setting of the recess 11 can effectively save production consumables of the FPC 1, is more environment-friendly, and can further save the production cost of the display panel 22.

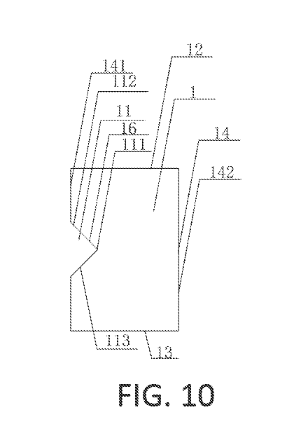

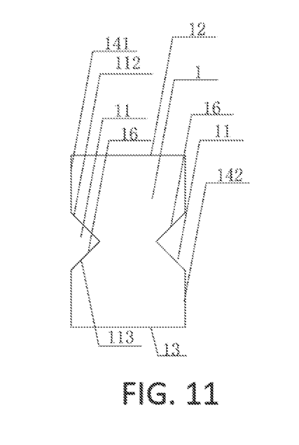

As still another embodiment of the present application, as shown in FIGS. 10 and 11, the second end of the first linear segment 112 and the second end of the second linear segment 113 are intersected with the side edge 14, separately. The recess 111 is provided at the central point of the side edge, and both ends of the recess 111 are connected to the endpoint of the first connecting edge 12 and the endpoint of the second connecting edge 13 by means of linear segments. Since the bending setting of the FPC 1 is generally performed on the central points of the first side edge 141 and the second side edge 142, the recess 111 is provided at the central point of the side edge 14, and the side edge to be bent can disperse the torque generated by bending the display panel 22, so that the stressed points on the FPC 1 are dispersed, thereby effectively avoiding the tearing of the FPC 1, effectively preventing the position where the FPC 1 is connected to the display panel 22 from being strained, and greatly reducing the reject ratio of the display panel 22 with a curved surface, without increasing any cost. Moreover, the recess 111 is only provided at the central point, and thus the area of the FPC 1 can be effectively enlarged, so that more package chips can be provided on the FPC 1, thereby ensuring the high utilization rate of the FPC 1.

Of course, multiple recesses 111 can be provided on the side edge, and the recess 11 may adopt other polygon settings, such as a square recess, and may also adopt a recess setting of an irregular shape, such as a waved recess.

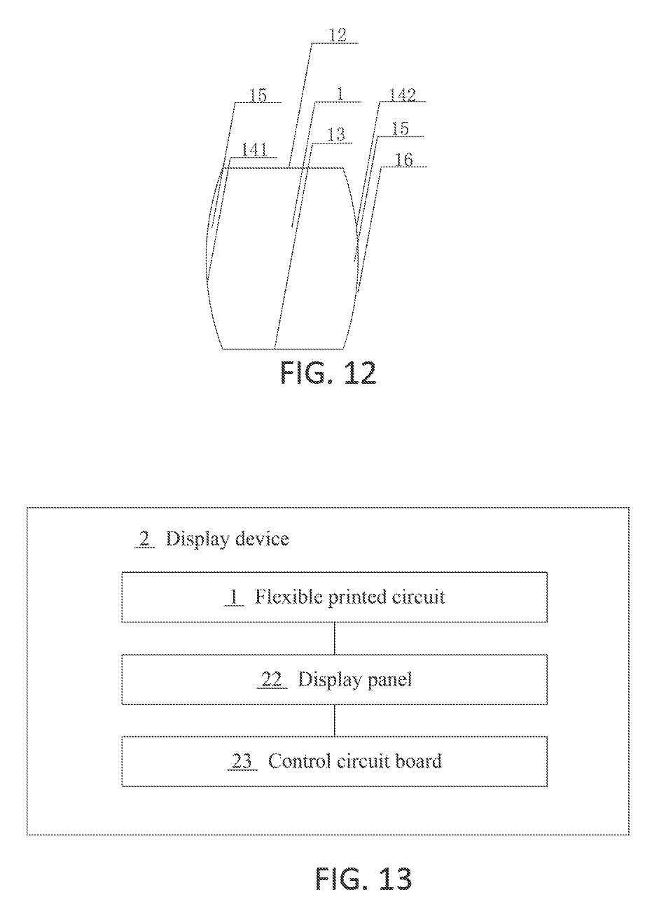

As still another embodiment of the present application, as shown in FIG. 12, the stress dispersion part 16 includes an arched part 15 provided on the side edge 14. The setting of the arched part 15 can effectively disperse the torque generated by bending the display panel 22. The stressed lines of the first side edge 141 and the second side edge 142 are broken to effectively disperse the stress, so that the stressed points on the FPC 1 are dispersed, thereby effectively avoiding the tearing of the FPC 1, effectively avoiding the position where the FPC 1 is connected to the display panel 22 from being strained, further enabling normal display of the display panel 22, ensuring the yield for manufacturing the display panel 22 with a curved surface, and effectively reducing the scrap cost of the display panel 22. Moreover, the wiring strain caused by pulling the bent FPC 1 can be reduced, thereby ensuring a better display effect of the display panel 22. Moreover, the FPC 1 can be made only by providing an arched part 15 on a side edge 14 of a chip on panel, so that the reject ratio of the display panel 22 with a curved surface can be greatly reduced without increasing any cost. Such setting can produce a better FPC 1 with the side edge 14 being provided with an arched part 15 only by simply modifying the existing production line, rather than replacing the entire production line; the modification cost is low, and therefore, the production cost is saved. Moreover, the FPC 1 on the prepared display panel 22 with a curved surface can also be simply modified, and therefore, the display effect of the display panel 22 can be greatly improved in low modification cost.

According to another aspect of the present application, as shown in FIG. 13, the present application also discloses a display device 2, which includes a display panel 22, a control circuit board 23, and the FPC 1.

In some embodiments, the display panel 22 may be an LCD, LED, OLED, QLED curved-surface display panel, or other display panels.

The contents above are further detailed descriptions of the present application in conjunction with the specific optionally embodiments, and the specific implementation of the present application is not limited to these descriptions. It will be apparent to those skilled in the art that various simple deductions or substitutions may be made without departing from the spirit of the present application, and should be considered to be within the scope of protection of the present application.

What is claimed is:

1. A Flexible Printed Circuit (FPC) applied to a display panel, comprising:
a first connecting edge connected to the display panel; and
a second connecting edge connected to a control circuit board;
both ends of the first connecting edge and the second connecting edge are connected and provided with a side edge on which a stress dispersion part is provided; the stress dispersion part comprises a recess provided on the side edge, and the profile of the recess is an arc segment; the recess is provided on the side edge; and one end of the recess is connected to an endpoint of the first connecting edge, and the other end of the recess is connected to an endpoint of the second connecting edge.

2. An FPC applied to a display panel, comprising:
a first connecting edge connected to the display panel; and
a second connecting edge connected to a control circuit board;
both ends of the first connecting edge and the second connecting edge are connected and provided with a side edge on which a stress dispersion part is provided.

3. The FPC applied to a display panel according to claim 2, wherein the side edge comprises a first side edge and a second side edge, and the stress dispersion part is provided on the first side edge or/and the second side edge.

4. The FPC applied to a display panel according to claim 2, wherein the stress dispersion part comprises an arched part provided on the side edge.

5. The FPC applied to a display panel according to claim 2, wherein the stress dispersion part comprises a recess provided on the side edge, and the profile of the recess is an are segment.

6. The FPC applied to a display panel according to claim 5, wherein the recess is provided on the side edge, one end of the recess is connected to an endpoint of the first connecting edge, and the other end of the recess is connected to an endpoint of the second connecting edge.

7. The FPC applied to a display panel according to claim 5, wherein both ends of the recess are intersected with the side edge.

8. The FPC applied to a display panel according to claim 2, wherein the profile of the recess comprises a first linear segment and a second linear segment; and a first end of the first linear segment is intersected with a first end of the second linear segment at a central position of the side edge.

9. The FPC applied to a display panel according to claim 8, wherein a second end of the first linear segment and a second end of the second linear segment are intersected with the first connecting edge and the second connecting edge respectively.

10. The FPC applied to a display panel according to claim 8, wherein the second end of the first linear segment and the second end of the second linear segment are intersected with the side edge separately.

11. A display device, comprising:
a display panel;
a control circuit board; and
an FPC;
the FPC comprises a first connecting edge connected to the display panel; and a second connecting edge connected to the control circuit board; both ends of the first connecting edge and the second connecting edge are connected and provided with a side edge on which a stress dispersion part is provided.

12. The display device according to claim 11, wherein the side edge comprises a first side edge and a second side edge, and the stress dispersion part is provided on the first side edge or/and the second side edge.

13. The display device according to claim 11, wherein the stress dispersion part comprises an arched part provided on the side edge.

14. The display device according to claim 11, wherein the stress dispersion part comprises a recess provided on the side edge, and the profile of the recess is an arc segment.

15. The display device according to claim 14, wherein the recess is provided on the side edge, one end of the recess is connected to an endpoint of the first connecting edge, and the other end of the recess is connected to an endpoint of the second connecting edge.

16. The display device according to claim 14, wherein both ends of the recess are intersected with the side edge.

17. The display device according to claim 11, wherein the profile of the recess comprises a first linear segment and a second linear segment, and a first end of the first linear segment is intersected with a first end of the second linear segment at a central position of the side edge.

18. The display device according to claim 17, wherein a second end of the first linear segment and a second end of the second linear segment are intersected with the first connecting edge and the second connecting edge respectively.

19. The display device according to claim 17, wherein the second end of the first linear segment and the second end of the second linear segment are intersected with the side edge separately.
